(19) United States
(12) Patent Application Publication
(10) Pub. No.: US 2024/0123535 A1
(43) Pub. Date: Apr. 18, 2024

(54) DISPLAY ASSEMBLIES AND WELDING-TYPE DEVICES HAVING DISPLAY ASSEMBLIES

(71) Applicant: Illinois Tool Works Inc., Glenview, IL (US)

(72) Inventor: Nathan Joe Jochman, Neenah, WI (US)

(21) Appl. No.: 17/965,210

(22) Filed: Oct. 13, 2022

(51) Int. Cl. B23K 9/10; H05K 5/03; H05K 5/06

(52) U.S. Cl. CPC B23K 9/1006; H05K 5/03; H05K 5/061; H05K 5/062

(57) ABSTRACT

Example welding-type devices include: a housing having a user interface on a first panel; and a display assembly configured to mount to the housing, the display assembly including: a display panel; a cover panel bonded to the display panel, the cover panel having at least one dimension larger than a corresponding dimension of the display panel; and a seal between the cover panel and the first panel.

### FIELD OF THE DISCLOSURE

This disclosure relates generally to welding-type systems and, more particularly, to display assemblies and welding-type devices having display assemblies.

### BACKGROUND

Conventional welding systems have different user interface approaches for displaying information. The range of display types include analog displays and gauges, segmented displays, LCD modules, and custom LCD displays integrated into the enclosure.

### SUMMARY

Display assemblies and welding-type devices having display assemblies are disclosed, substantially as illustrated by and described in connection with at least one of the figures.

### BRIEF DESCRIPTION OF THE DRAWINGS

FIG. 1 is a block diagram of an example welding-type device, in accordance with aspects of this disclosure.

FIGS. 2A and 2B are exploded perspective views of the example display assembly of FIG. 1.

FIGS. 3A and 3B are exploded perspective views of an panel of the housing of the welding-type device, a display assembly of the welding-type device, and a trim panel of the welding-type device, in accordance with aspects of this disclosure.

FIG. 4 is a perspective view of the example display assembly of FIGS. 2A-3B installed in the panel.

FIG. 5 is an elevation view of the example display assembly of FIGS. 2A-3B installed in the panel.

The figures are not necessarily to scale. Where appropriate, similar or identical reference numbers are used to refer to similar or identical components.

### DETAILED DESCRIPTION

For conventional outdoor welding equipment, LCD/digital displays are screens enclosed in plastic modules with protective lenses, gasketed perimeters, and sealed connectors. These modules are often sourced from display companies and are of a high cost. These conventional modules are attached to an outside surface of a machine by bolting or similar attachments. In addition to the high expense of such conventional LCD modules, such modules are bulky and occupy high amounts of space, create ingress points for water and/or dust, suffer from fogging due to air gas between the display and the exterior lens, suffer from cracking due to impacts common in outdoor environments, and/or require excess cost and labor to replace.

Disclosed example welding-type devices and methods provide an improved display assembly which addresses the foregoing problems with conventional welding equipment. Disclosed example welding-type devices have particular advantages in welding-type equipment intended for use in outdoor environments, but are an improvement for any industrial equipment.

In some disclosed examples, a display assembly is attached to a welding-type device. Disclosed example display assemblies have a display (e.g., an LCD, LED, OLED screen) that is optically bonded on the front side to a piece of cover glass. The display has a cable or other connector on the back side that connects to driver or control circuitry located behind the panel (e.g., inside the enclosure of the welding-type device). The cover glass may be selected for impact resistance, and is dimensioned such that the perimeter of the cover glass overhangs the display for contact with a panel into which the display assembly is installed. The glass has an adhesive or other seal on the panel side for attachment and sealing of the cover glass to the panel, which also holds the display in place. The installation panel has an aperture or recess, which is sized to allow insertion of the display and to provide surfaces around the aperture or recess for attachment of the cover glass to the panel.

Disclosed examples lower the replacement and repair costs of the display by allowing the display to be replaced without also requiring replacement of a driver or user interface module, as well as by providing serviceability and replacement of the display from the exterior of the outside of the equipment enclosure. Disclosed examples have improved visibility of the display using impact resistant cover layers and by optically bonding the display to the cover layer to reduce fogging and/or diffraction. Example welding-type devices have improved protection from fluid and particulate by limiting the ingress points to the seal between the display assembly and the panel. Disclosed examples provide improved impact resistance by allowing for thicker and better protective layers (e.g., glass), since the glass is not part of a pre-designed assembly and can be configured or selected for a particular application.

Disclosed example welding-type devices include: a housing having a user interface on a first panel; and a display assembly configured to mount to the housing, in which the display assembly includes: a display panel; a cover panel bonded to the display panel, the cover panel having at least one dimension larger than a corresponding dimension of the display panel; and a seal between the cover panel and the first panel.

Some example welding-type devices further include a display driver board positioned within the housing, the display driver board comprising circuitry configured to control an output of the display panel. In some example welding-type devices, a connector of the display panel is configured to connect to a connector of the display driver board. In some example welding-type devices, the connector of the display panel includes at least one of a ribbon cable or a serial bus cable. In some example welding-type devices, the display assembly is replaceable without requiring replacement of the display driver board.

In some example welding-type devices, the display panel is an LCD screen, an LED screen, or an OLED screen. In some example welding-type devices, the cover panel includes a chemically treated glass. In some example welding-type devices, the first panel includes at least one of a display aperture or display recess, in which the display panel is configured to fit within the display aperture or display recess, and the cover panel has at least one dimension larger than the display aperture or display recess such that the cover panel contacts the first panel when the display panel is within the display aperture or display recess. In some example welding-type devices, the cover panel extends beyond the display aperture or display recess in two dimensions.

In some example welding-type devices, the seal includes an adhesive configured to adhere the cover panel directly to the first panel of the housing along a perimeter of the cover panel. In some example welding-type devices, the adhesive provides ingress protection against fluids and dust between the cover panel and the first panel. In some example welding-type devices, the seal includes a gasket configured to seal between the cover panel and the first panel of the housing along a perimeter of the cover panel, and the cover panel is attached to the first panel by one or more fasteners.

Some example welding-type devices further include a trim panel configured to cover the cover panel at least over the adhesive and to provide structural support to the display assembly. In some example welding-type devices, the trim panel is attached to the first panel after installation of the display assembly.

In some example welding-type devices, the user interface includes one or more input devices. In some example welding-type devices, the welding-type device is at least one of a welding-type power supply, a wire feeder, or a remote control device. In some example welding-type devices, the cover panel is optically bonded to the display panel via a bonding material disposed between the cover layer and the display panel, the bonding material filling gaps between the cover layer and the display panel. In some example welding-type devices, the bonding material is at least one of silicone, glue, epoxy, or polyurethane.

Some example welding-type devices further include: an engine within the housing; a generator within the housing, wherein the generator is configured to convert mechanical power from the engine to electrical power; and at least one of: an air compressor coupled to at least one of the electrical power from the generator or the mechanical power from the engine and configured to output compressed air; welding-type conversion circuitry configured to convert the electrical power from the generator to welding-type power; a hydraulic pump configured to generate hydraulic pressure from at least one of the electrical power from the generator or the mechanical power from the engine; or auxiliary power conversion circuitry configured to convert the electrical power from the generator to at least one of AC output power or DC output power.

Disclosed example display assemblies include: a display panel having a connector configured to connect to display driver circuitry; a cover panel bonded to the display panel, the cover panel having at least one dimension larger than a corresponding dimension of the display panel; and a seal configured to provide a seal between a face of the cover panel and a surface to which the cover panel is installed, the display panel being bonded to the face of the cover panel and the seal being around a perimeter of the display panel.

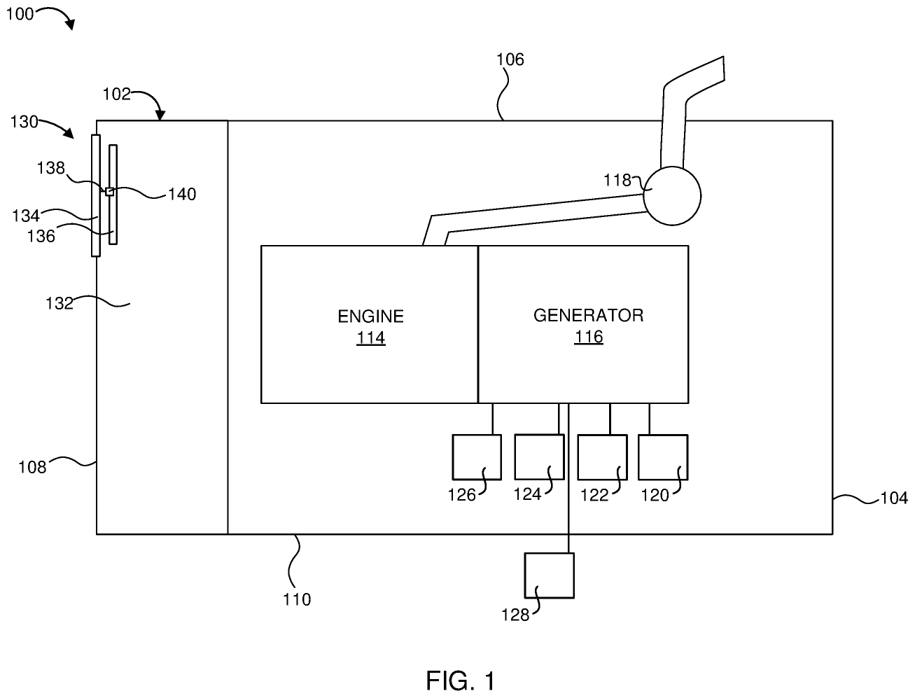

FIG. 1 is a block diagram of an example welding-type device 100. The example welding-type device 100 of FIG. 1 is an engine-driven welding power supply. However, the disclosed methods and apparatus may be implemented in any welding-type equipment, such as power supplies, wire feeders, remote control devices (e.g., pendants), and/or any other welding-type or other equipment having a display screen. The welding-type device 100 of FIG. 1 may be used for various applications, such as, for example, providing compressed air, generating power, pumping, and/or welding support.

The example welding-type device 100 may include other components not specifically discussed herein, or may omit one or more of the components discussed herein. The components of the welding-type device 100 may be arranged within an enclosure 102 in any suitable configuration.

As illustrated in FIG. 1, the welding-type device 100 includes the enclosure 102. The enclosure 102 protects internal components of the welding-type device 100 from the environment, as well as providing a safety, sound, and aesthetic barrier for an operator using or within range of the welding-type device 100. The enclosure 102 is primarily constructed with sheet metal, and may include multiple panels. For example, the enclosure 102 may include the rear panel 104, a top panel 106, a front panel 108, side panels, and a bottom panel 110 when installed in a predetermined orientation (e.g., when the welding-type device 100 is installed in accordance with the intended use of the welding-type device 100).

Any of the rear panel 104, the top panel 106, the front panel 108, the side panels, or the bottom panel 110 may include multiple panels. One or more of the panels may be removable and/or one or more of the panels may open, to permit access. In other examples, some or all of the panels (e.g., the rear panel 104) may include a single, unitary panel.

In some examples, one or more of the rear panel 104, the top panel 106, the front panel 108, the side panels, or the bottom panel 110 may define additional features. For example, the rear panel 104 may define louvers 112 to permit airflow into or out of the enclosure 102. Additionally, or alternatively, the rear panel 104 may include other features, such as, for example, features that extend at a non-zero angle from a center surface (discussed in more detail below) of the rear panel 104, apertures, cut-outs, or the like. Any of the rear panel 104, the top panel 106, the front panel 108, the side panels, or the bottom panel 110 may include additional or alternative features.

While the enclosure 102 is described herein as including six sides—the rear panel 104, the top panel 106, the front panel 108, two side panels, and the bottom panel 110, this naming convention is for ease of description only. Indeed, one or more of the rear panel 104, the top panel 106, the front panel 108, the side panels, or the bottom panel 110 may form a portion of another of the rear panel 104, the top panel 106, the front panel 108, the side panels, or the bottom panel 110. For example, the rear panel 104 may define a transition from a center surface of the rear panel 104 to a flange that is perpendicular to the center surface (e.g., along the top of the enclosure 102). In this way, the rear panel 104 may define a portion of the top of the enclosure 102. Thus, the rear panel 104 should be understood to include the surface of the enclosure 102 that defines the majority of a rear end of the enclosure 102; the top panel 106 should be understood to include the surface of the enclosure 102 that defines the majority of a top end of the enclosure 102; the front panel 108 should be understood to include the surface of the enclosure 102 that defines the majority of a front end of the enclosure 102; each side panel should be understood to include a surface of the enclosure 102 that defines the majority of a side of the enclosure 102; and the bottom panel 110 should be understood to include the surface of the enclosure 102 that defines the majority of a bottom end of the enclosure 102. In some examples, each of the rear panel 104, the top panel 106, the front panel 108, the side panels, or the bottom panel 110 is an unbroken piece of material. In some such examples, the unbroken piece of material may include multiple portions defining different shapes (e.g., a flat center portion, a flange, etc.) and/or directions (e.g., front, rear, top, sides, or bottom).

The welding-type device 100 includes an engine 114 that drives a generator 116 to generate electrical power. The engine 114 may be an internal combustion engine, a diesel engine, a fuel cell, etc. The engine 114 is configured to output mechanical power to drive the generator 116. The engine 114 receives fuel from a fuel tank.

In some examples, the welding-type device 100 includes one or more power subsystems. For example, the generator 116 may provide the electrical power to welding-type conversion circuitry 120 configured to output welding-type power, an air compressor 122 configured to output pneumatic power, a hydraulic pump 124 configured to output hydraulic flow, auxiliary power conversion circuitry 126 configured to output AC power and/or DC power (e.g., DC and/or AC electrical output(s)), and/or any other load device. The example hydraulic pump 124 and the air compressor 122 may be powered by mechanical power from the engine 114 and/or by electrical power from the generator 116.

In some examples, an external power supply subsystem 128 may be coupled (e.g., plugged in, hardwired, etc.) to the welding-type device 100 to convert at least one of the AC power or the DC power from the auxiliary power conversion circuitry 126 and/or the generator 116 to at least one of AC power or DC power, such as to power external devices that have different power requirements. The example external power supply subsystem 128 may also be communicatively coupled to control circuitry 132 of the welding-type device 100 (e.g., wirelessly, via power line communication, via a communication cable, etc.) to enable the control circuitry 132 to control the demand and/or output of the external power supply subsystem 128.

The welding-type conversion circuitry 120 converts output power from the generator 116 (e.g., via the intermediate voltage bus) to welding-type power based on a commanded welding-type output. The welding-type conversion circuitry 120 provides current at a desired voltage to an electrode and a workpiece via output terminals to perform a welding-type operation. The welding-type conversion circuitry 120 may include, for example, a switched mode power supply or an inverter fed from an intermediate voltage bus. The welding-type conversion circuitry 120 may include a direct connection from a power circuit to the output (such as to the weld studs), and/or an indirect connection through power processing circuitry such as filters, converters, transformers, rectifiers, etc.

The auxiliary power conversion circuitry 126 converts output power from the generator 116 (e.g., via the intermediate voltage bus) to AC power (e.g., 120 VAC, 240 VAC, 50 Hz, 60 Hz, etc.) and/or DC power (e.g., 12 VDC, 24 VDC, battery charging power, etc.). The auxiliary power conversion circuitry 126 outputs one or more AC power outputs (e.g., AC outlets or receptacles) and/or one or more DC power outputs (e.g., DC outlets or receptacle). The welding-type device 100 enables multiple ones of the power subsystems (e.g., the hydraulic pump, the air compressor 122, the welding-type conversion circuitry 120, the auxiliary power conversion circuitry 126, the external power supply subsystem 128, etc.) to be operated simultaneously.

In some examples, the welding-type device 100 includes a user interface 130. The user interface 130 includes one or more input device(s) configured to receive inputs selecting mode(s) representative of welding-type processes, mode(s) representative of one or more battery charging modes, mode(s) representative of a vehicle load, and/or other modes such as a pneumatic load and/or a hydraulic load, and/or inputs to navigate a graphical user interface presented on a display. The user interface 130 further includes a display assembly 134 attached to the front panel 108, such as to provide a graphical user interface for control of the welding-type device.

As disclosed in more detail below, the display assembly 134 may be mounted or attached to the front panel 108 in a manner that allows the display assembly 134 to be replaced without having to replace a large expensive UI module, such as a display driver board 136 which is typically integrated into a display assembly and is therefore also removed when the display is removed. The display driver board 136 includes circuitry which provides display information or signals to the display (e.g., an LCD, LED, or OLED display) to control the display (e.g., based on information from the control circuitry 132) to output the desired display information. In disclosed examples, the display assembly 134 is replaceable from the outside of the enclosure 102, which avoids removal or disassembly of parts of the enclosure 102 to access and remove the display assembly 134.

When installed, the display assembly 134 is connected to the display driver board 136 via a display connector 138 (e.g., a ribbon cable, a serial bus cable, etc.) and a driver connector 140. For example, the display connector 138 may be repeatedly connected and disconnected from the driver connector 140.

The welding-type device 100 includes an exhaust system 118. In some examples, the exhaust system 118 includes a muffler and a tail pipe. The exhaust system 118 is configured to release exhaust gases from the engine 114 external to the enclosure 102 and reduce the sound of the engine 114 during operation.

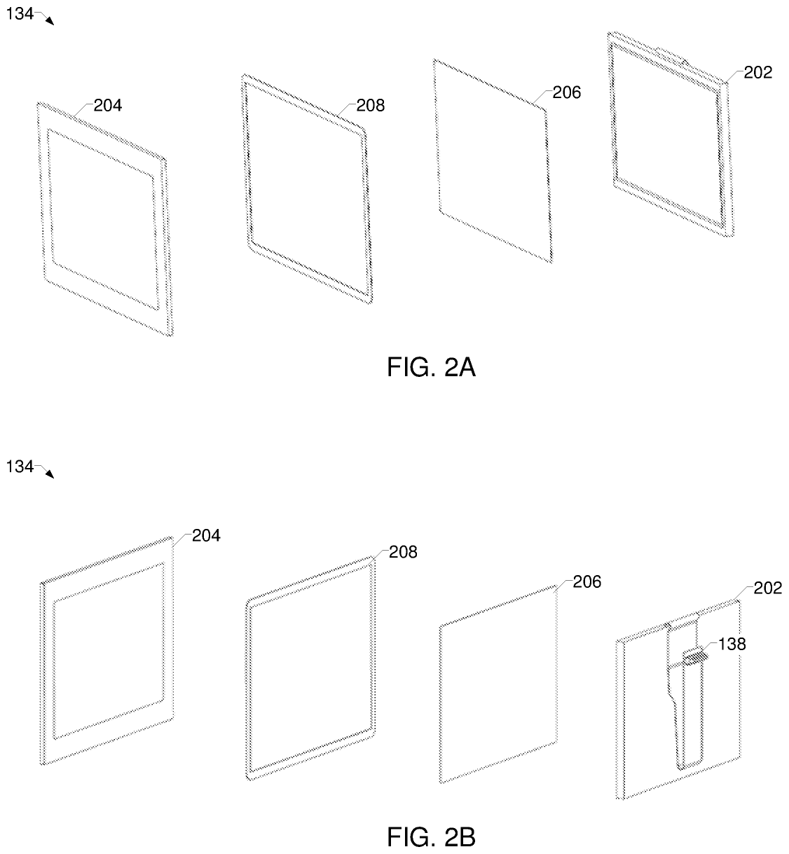

FIGS. 2A and 2B are exploded perspective views of the example display assembly 134 of FIG. 1. The example display assembly 134 includes a display panel 202, which provides a visual output based on input signals (e.g., from the display driver board 136). The display assembly 134 further includes a cover panel 204. The cover panel 204, such as glass or rigid plastic, protects the more delicate display assembly 134 from mechanical damage. The cover panel 204 may be chemically treated to improve resistance to impact damage and/or scratching, and/or the thickness of the cover panel 204 is selectable for the desired strength without affecting the positioning of the display panel 202 with respect to the front panel 108. As discussed in more detail below, the cover panel 204 is larger in one or more dimensions than the display panel 202.

The cover panel 204 is bonded to the display panel 202. In the example of FIGS. 2A and 2B, the cover panel 204 is optically bonded to the display panel 202 via a silicone, glue, epoxy, polyurethane or other or other adhesive bonding material 206 which improves the visibility of the display panel 202 through the cover panel 204. For example, the bonding material 206 may be applied as a transparent liquid which displaces air and fills gaps between the cover panel 204 and the display panel 202. The bonding material 206 may then cure to mechanically bond the cover panel 204 and the display panel 202.

The example display assembly 134 further includes a seal 208, which is positioned between the cover panel 204 and the front panel 108. The seal 208 extends a perimeter of the cover panel 204 to reduce or prevent ingress of fluid and/or particulates into the enclosure 102.

The seal 208 may be an adhesive strip or compound, which may provide both sealing and mechanical attachment of the cover panel 204 to the front panel 108. Alternatively, the seal 208 may be a gasket that is tightened between the cover panel 204 and the front panel 108 using fasteners (e.g., screws, clips, etc.) or other mechanical attachment.

As illustrated in FIG. 2B, the display connector 138 extends from the rear of the display panel 202 for connection to the display driver board 136 through the front panel 108. The display connector 138 (e.g., ribbon cable, serial bus cable) is long enough to provide an easy connection to the driver connector 140 when the display assembly 134 is being installed.

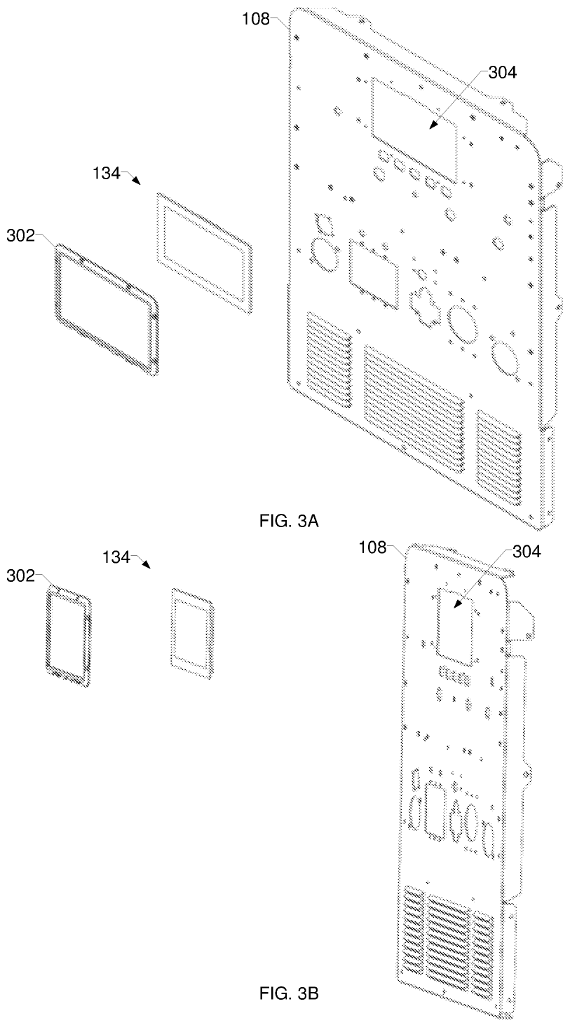

FIGS. 3A and 3B are exploded perspective views of the front panel 108 of the enclosure 102 of the welding-type device 100, the display assembly 134, and a trim panel 302. As illustrated in FIGS. 3A and 3B, the example front panel 108 of FIG. 2A includes a display aperture 304. The display aperture 304, the display panel 202, and the cover panel 204 may be sized such that the display panel 202 fits through the display aperture 304, but the cover panel 204 is larger in one or both dimensions than the display aperture 304. For example, the cover panel 204 may extend beyond the display aperture 304 by a distance to enable sufficient surface area between the chosen adhesive or gasket and the front panel 108 to obtain adequate strength and sealing performance.

During installation, the display connector 138 is connected to the driver connector 140 through the display aperture 304. The seal 208 (e.g., adhesive) may then be installed, applied, exposed, or otherwise prepared for disposal between the first panel and the perimeter of the cover panel 204 (e.g., the outermost 0.5 to 1 inch of the face of the cover panel 204 contacting the front panel 108). The display assembly 134 is then installed onto the front panel 108 such that the display panel 202 is inserted into the display aperture 304 until the cover panel 204 and the seal 208 contact and establish a seal against the front panel 108.

In other examples, the display aperture 304 may be replaced with a pocket or recess in the front panel 108, into which the display panel 202 is inserted. The recess or pocket has dimensions such that the display panel 202 is recessed from a face of the front panel 108, but the cover panel 204 makes contact with the face of the front panel 108. Such a pocket or recess may include one or more smaller apertures for insertion of the display connector 138 and/or other cables or conductors.

The outer edges of the example display assembly 134 may be concealed by the trim panel 302, which is fastened to the front panel 108 after installation of the display assembly 134. The trim panel 302 further provides structural support to the display assembly 134.

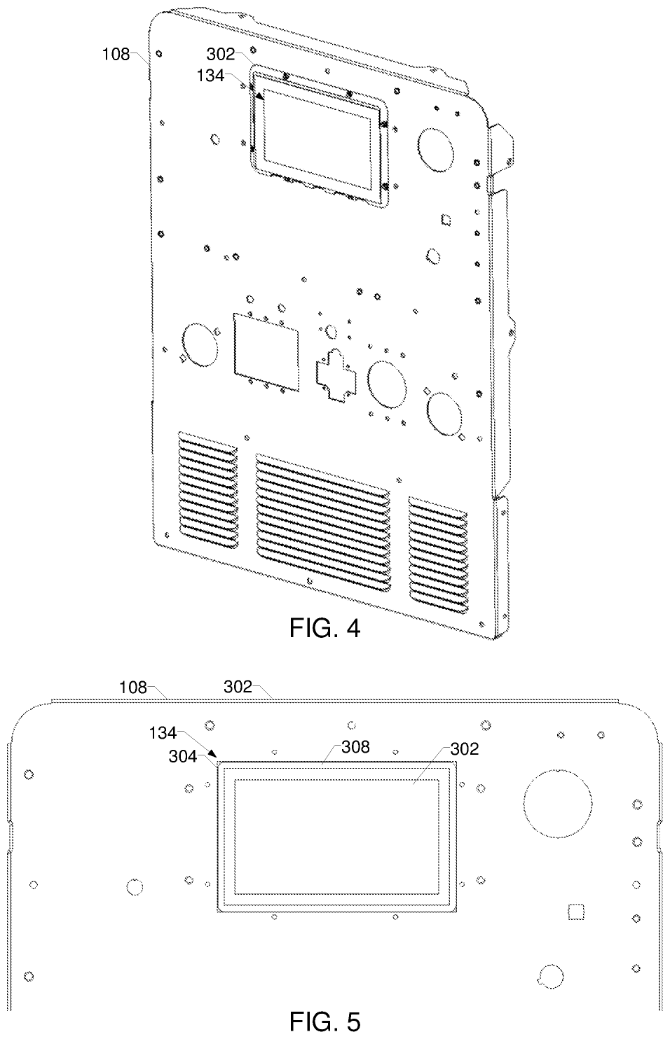

FIG. 4 is a perspective view of the example display assembly 134 of FIGS. 2A-3B installed in the front panel 108. FIG. 5 is an elevation view of the example display assembly 134 of FIGS. 2A-3B installed in the front panel 108 without the trim panel 302. In FIGS. 4 and 5, the cover panel 204 is shown as transparent to illustrate the placement of the seal 208 and the display panel 202. However, in some examples, the perimeter of the cover panel 204 may be tinted or otherwise darkened to obscure the seal 208 and/or improve aesthetics.

To remove the display assembly 134, the trim panel 302 is removed. The display assembly 134 may then be pried off (e.g., for adhesive seals) or otherwise detached (e.g., via detaching fasteners and a gasket) from the front panel 108. The display assembly 134 can then be removed from the front panel 108 and the display connector 138 disconnected from the driver connector 140.

As utilized herein, “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.,” and “for example” set off lists of one or more non-limiting examples, instances, or illustrations.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. For example, systems, blocks, and/or other components of disclosed examples may be combined, divided, re-arranged, and/or otherwise modified. Therefore, the present method and/or system are not limited to the particular implementations disclosed. Instead, the present method and/or system will include all implementations falling within the scope of the appended claims, both literally and under the doctrine of equivalents.

What is claimed is:

1. A welding-type device, comprising:
a housing having a user interface on a first panel; and
a display assembly configured to mount to the housing, the display assembly comprising:
a display panel;
a cover panel bonded to the display panel, the cover panel having at least one dimension larger than a corresponding dimension of the display panel; and
a seal between the cover panel and the first panel.

2. The welding-type device as defined in claim 1, further comprising a display driver board positioned within the housing, the display driver board comprising circuitry configured to control an output of the display panel.

3. The welding-type device as defined in claim 2, wherein a connector of the display panel is configured to connect to a connector of the display driver board.

4. The welding-type device as defined in claim 3, wherein the connector of the display panel comprises at least one of a ribbon cable or a serial bus cable.

5. The welding-type device as defined in claim 2, wherein the display assembly is replaceable without requiring replacement of the display driver board.

6. The welding-type device as defined in claim 1, wherein the display panel is an LCD screen, an LED screen, or an OLED screen.

7. The welding-type device as defined in claim 1, wherein the cover panel comprises a chemically treated glass.

8. The welding-type device as defined in claim 1, wherein the first panel comprises at least one of a display aperture or display recess, the display panel is configured to fit within the display aperture or display recess, and the cover panel has at least one dimension larger than the display aperture or display recess such that the cover panel contacts the first panel when the display panel is within the display aperture or display recess.

9. The welding-type device as defined in claim 8, wherein the cover panel extends beyond the display aperture or display recess in two dimensions.

10. The welding-type device as defined in claim 1, wherein the seal comprises an adhesive configured to adhere the cover panel directly to the first panel of the housing along a perimeter of the cover panel.

11. The welding-type device as defined in claim 1, wherein the adhesive provides ingress protection against fluids and dust between the cover panel and the first panel.

12. The welding-type device as defined in claim 1, wherein the seal comprises a gasket configured to seal between the cover panel and the first panel of the housing along a perimeter of the cover panel, and the cover panel is attached to the first panel by one or more fasteners.

13. The welding-type device as defined in claim 1, further comprising a trim panel configured to cover the cover panel at least over the adhesive and to provide structural support to the display assembly.

14. The welding-type device as defined in claim 13, wherein the trim panel is attached to the first panel after installation of the display assembly.

15. The welding-type device as defined in claim 1, wherein the user interface comprises one or more input devices.

16. The welding-type device as defined in claim 1, wherein the welding-type device is at least one of a welding-type power supply, a wire feeder, or a remote control device.

17. The welding-type device as defined in claim 1, wherein the cover panel is optically bonded to the display panel via a bonding material disposed between the cover layer and the display panel, the bonding material filling gaps between the cover layer and the display panel.

18. The welding-type device as defined in claim 17, wherein the bonding material is at least one of silicone, glue, epoxy, or polyurethane.

19. The welding-type device as defined in claim 1, further comprising:
an engine within the housing;
a generator within the housing, wherein the generator is configured to convert mechanical power from the engine to electrical power; and
at least one of:
an air compressor coupled to at least one of the electrical power from the generator or the mechanical power from the engine and configured to output compressed air;
welding-type conversion circuitry configured to convert the electrical power from the generator to welding-type power;
a hydraulic pump configured to generate hydraulic pressure from at least one of the electrical power from the generator or the mechanical power from the engine; or
auxiliary power conversion circuitry configured to convert the electrical power from the generator to at least one of AC output power or DC output power.

20. A display assembly, the display assembly comprising:
a display panel having a connector configured to connect to display driver circuitry;
a cover panel bonded to the display panel, the cover panel having at least one dimension larger than a corresponding dimension of the display panel; and
a seal configured to provide a seal between a face of the cover panel and a surface to which the cover panel is installed, the display panel being bonded to the face of the cover panel and the seal being around a perimeter of the display panel.
